(19) United States
(12) Patent Application Publication
(10) Pub. No.: US 2004/0150413 A1
(43) Pub. Date: Aug. 5, 2004

(54) Cantilever having improved resolution and manufacturing method therof

(75) Inventor: Hitoshi Maeda, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/646,892

(22) Filed: Aug. 25, 2003

(30) Foreign Application Priority Data
Feb. 5, 2003 (JP) 2003-027851

(51) Int. Cl. G12B 21/02; G01R 3/00; G01N 13/20

(52) U.S. Cl. 324/690; 73/105; 216/13; 29/595

(57) ABSTRACT

The present invention provides a cantilever which enables a further improvement of a surface resolution capability of a scanning capacity microscope (SCM) with regard to a cantilever employed for the SCM, as compared with a case of employing a conventional cantilever. As the cantilever applied to the SCM according to the present invention, that cantilever has a probe part 1 scanning a sample and an electrode part 2 supporting that probe part 1. Moreover, that probe part 1 includes an insulator 1a having a square pyramidal shape and a conductive wiring 1b placed only on one surface of that insulator 1a having the square pyramidal shape.

### BACKGROUND OF THE INVENTION

1. Field of the Invention

The present invention relates to a structure of a cantilever and a manufacturing method thereof, and for example, it relates to a cantilever which is applicable to a scanning capacity microscope and a manufacturing method thereof.

2. Description of the Background Art

Conventionally, a scanning capacity microscope (mentioned as SCM hereinafter) is employed as a device to detect a distribution of an electrostatic capacity on a surface of a sample by making a probe part approach and scan the surface of the sample and measuring the electrostatic capacity formed between electric charges of the probe part and the surface of the sample (for example, refer to FIG. 2 of Japanese Patent Application Laid-Open No. 8-136555 (1996)).

With regard to measurement by the SCM, a conductive cantilever is employed, and for example, a cantilever that conductors such as Pt, CoCr and so on coat an entire surface of a non-doped silicon chip is employed.

However, with regard to the SCM, measurement is performed employing an electric force which is influenced over a long distance as compared with an atomic force, thus a surface resolution capacity of that SCM is influenced not only by a microscopic shape at an extreme edge of the probe part set to the cantilever but also by a macroscopic shape near the edge of that probe part.

Here, the surface resolution capability is an indication showing a performance of a microscope and so on and a value indicating a capacity limit that an identification and a detection are possible while separating different two points in a space.

Then, in a standpoint of the electric force which is a long-distance force (that is to say, in a macroscopic standpoint), it is suggested that the probe part that only one surface of it having a triangular pyramid shape is coated with the conductor is applied to the probe part of the cantilever of the SCM to control an influence of a part which does not relate to a direct observation of the probe part of the cantilever (for example, “Lecture Manuscripts of 49th Applied Physics Relation Joint Lecture Meeting”, March 2002, Shonan School Building in Tokai University, pp. 687).

However, in case that the coating of the conductor is performed on only one surface of the probe part having the triangular pyramid shape set to the cantilever, the surface resolution capability is improved as compared with a case that the coating of the conductor is performed on the entire surface of the triangular pyramid, however, there is a limitation in the improvement of that surface resolution capability.

### SUMMARY OF THE INVENTION

It is an object of the present invention to provide a cantilever which enables a further improvement of a surface resolution capability of microscopes such as a SCM and so on and a manufacturing method thereof.

The present invention relates to a cantilever which has a probe part scanning an observed sample and an electrode part supporting the probe part. According to the present invention, the probe part constituting the cantilever includes an insulator and a conductive wiring. The insulator has a sharp-pointed solid shape. The conductive wiring is placed on a part of a side surface of the insulator, one edge of it reaches a peak of the solid shape and an opposite edge of it reaches the electrode part.

For example, by applying that cantilever to the microscopes such as the SCM and so on, an area that the conductor except for an extreme edge part of the probe part relating to a direct measurement faces with the observed sample becomes small, and an influence of the conductor of a part which does not relate to the measurement directly can be controlled. Accordingly, corresponding to that control, a surface resolution capability of the SCM can also be made to improve.

According to the present invention, a manufacturing method of a cantilever includes steps (a), (b), (c), (d), (e) and (f). The step (a) is a step of forming a hole having a sharp-pointed solid shape in a surface of a substrate so that a peak is formed inside of that substrate. The step (b) is a step of forming a sacrifice film to cover the surface of the substrate and a side surface of the hole having the solid shape. The step (c) is a step of forming a conductive wiring in the side surface part of the hole having the solid shape on the sacrifice film so that one edge of it reaches a peak of the hole having the solid shape. The step (d) is a step of embedding an insulator having a selective etching rate to the sacrifice film to fill up the hole having the solid shape after the step (c). The step (e) is a step of forming an electrode part to cover an upper surface of the insulator, an opposite edge of the conductive wiring and the sacrifice film. The step (f) is a step of separating the insulator, the conductive wiring and the electrode part from the substrate by etching the sacrifice film after the step (e).

It can become possible to take out the cantilever composed of the conductive wiring and the insulator from the substrate by employing a simple etching (lift-off) treatment.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a drawing illustrating a section of a cantilever according to the present invention.

FIG. 2 is a drawing illustrating an appearance when observing the cantilever according to the present invention from the other direction.

FIG. 3 is a perspective view illustrating an appearance of a single crystal silicon substrate where a hole is formed.

FIG. 4 is a drawing illustrating an appearance that a silicon oxide film which is a sacrifice film is formed.

FIG. 5 is a drawing illustrating an appearance that a tungsten film is formed.

FIG. 6 is a cross sectional view illustrating an appearance that a photoresist to form a tungsten wiring is formed.

FIG. 7 is plane view illustrating an appearance that the photoresist to form the tungsten wiring is formed.

FIG. 8 is perspective view illustrating an appearance that the tungsten wiring is placed.

FIG. 9 is a drawing illustrating an appearance that a silicon nitride film is filled up in the hole.

FIG. 10 is a drawing illustrating an appearance that an extra silicon nitride film is removed.

FIG. 11 is a drawing illustrating an appearance that a platinum film is formed.

FIG. 12 is a drawing illustrating an appearance that the photoresist patterned in a determined shape is formed.

FIG. 13 is a drawing illustrating an appearance of the platinum film patterned in a determined shape.

FIG. 14 is a drawing illustrating an appearance that the cantilever is taken out from the single crystal silicon substrate.

### DESCRIPTION OF THE PREFERRED EMBODIMENTS

The present invention is concretely described on the basis of drawings illustrating the preferred embodiment hereinafter.

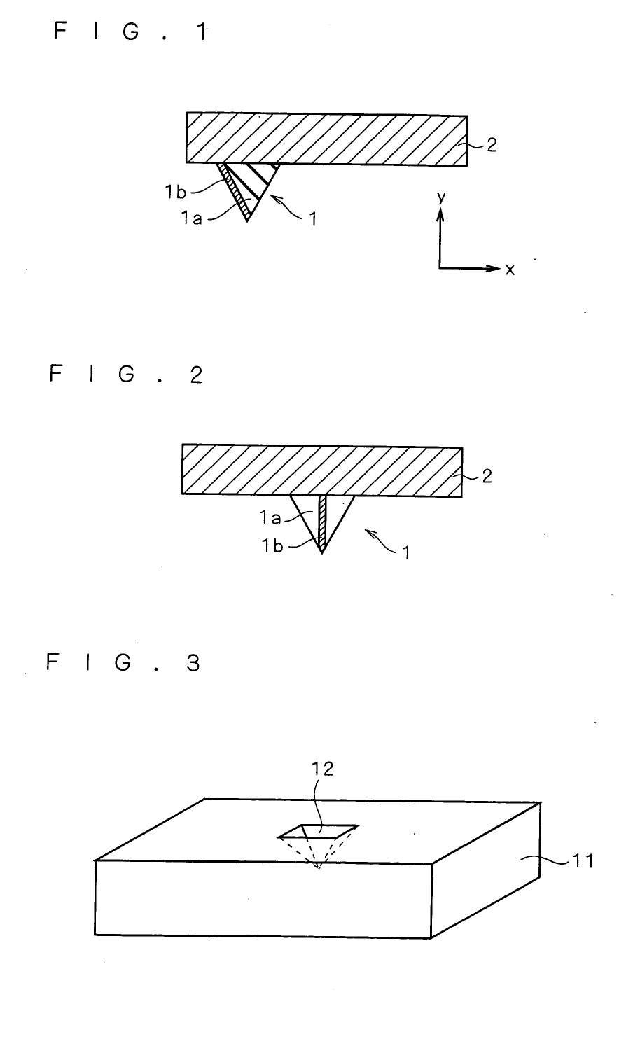

One preferred embodiment of the cantilever according to the present invention is illustrated in FIGS. 1 and 2. Here, FIG. 1 is a cross sectional view of that cantilever, and FIG. 2 is a drawing when that cantilever is seen from an X direction of a right-handed coordinate system shown in FIG. 1.

As shown in FIGS. 1 and 2, the cantilever of the present invention is composed of an electrode part 2 having a platy shape and a probe part 1 which is formed on an edge region of the electrode part 2 and scans a sample.

The probe part 1 is composed of an insulator 1a having a square pyramidal shape and a conductive wiring 1b. The conductive wiring 1b is placed on one surface of the insulator 1a having the square pyramidal shape, and placed to reach the electrode part 2 having the platy shape from a peak of that square pyramid through a center part of the one surface. That is to say, it is placed to make a length of the conductive wiring 1b become the shortest.

Here, in the present preferred embodiment, nitride silicon is applied as the insulator 1a, and tungsten is applied as the conductive wiring 1b. Moreover, platinum is applied as the electrode part 2 having the platy shape.

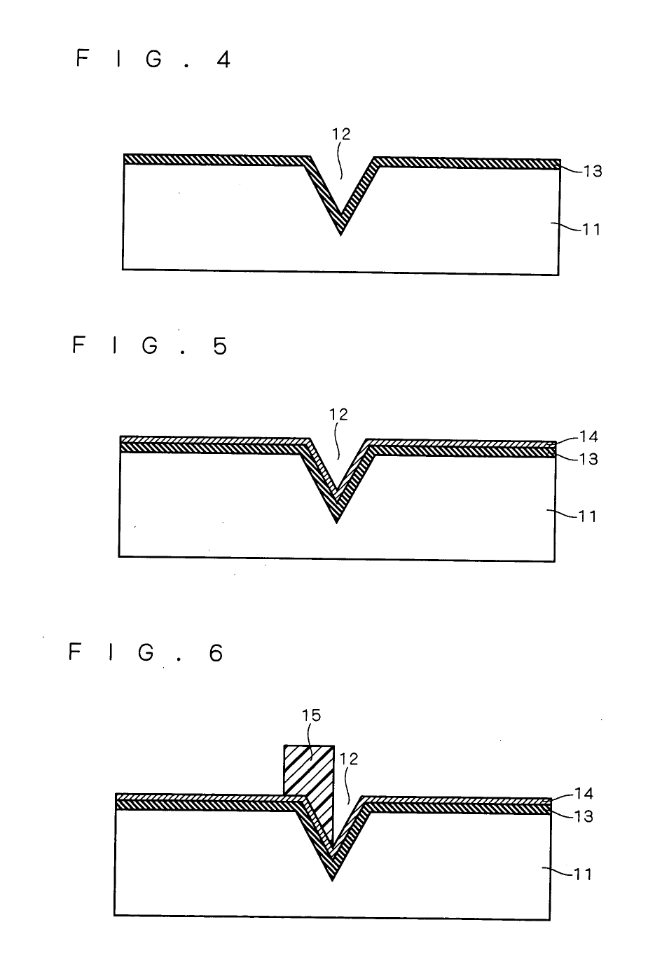

Next, one example of the manufacturing method of the cantilever shown in FIGS. 1 and 2 is described on the basis of FIGS. 3 to 14. Here, FIGS. 3 to 14 illustrate cross sectional views or perspective views of the cantilever on the way of manufacturing in respective manufacturing stages.

First, in the beginning, a single crystal silicon substrate 11 of a (100) main surface is prepared and a mask is placed on the main surface of that single crystal silicon substrate 11. Next, an opening part having a square shape of a determined size is formed in a determined point of the mask (the single crystal silicon substrate 11 is exposed from that opening part).

By immersing the single crystal silicon substrate 11 with that mask in an etching solution such as potassium hydroxide (KOH) aqueous solution and so on, a crystal anisotropy etching is performed (now, the single crystal silicon substrate 11 of the (100) surface is employed, thus that etching stops automatically on (111) a surface), and a hole 12 having a square pyramidal shape in a depth of approximately 10 μm is formed. After that, an appearance that the mask is removed is illustrated in FIG. 3.

Next, by employing a CVD (Chemical Vapor Deposition) method, a silicon oxide film 13 as a sacrifice film is formed in a thickness of approximately 100 nm to cover a side surface of the hole 12 having the square pyramidal shape and a main surface of the single crystal silicon substrate 11 as shown in FIG. 4.

Next, by employing the CVD method, a tungsten film 14 is formed in a thickness of approximately 10 μm to cover the silicon oxide film as shown in FIG. 5. Besides, the forming treatment can also be performed by employing the other material, if it has a conductivity as a film to be formed here.

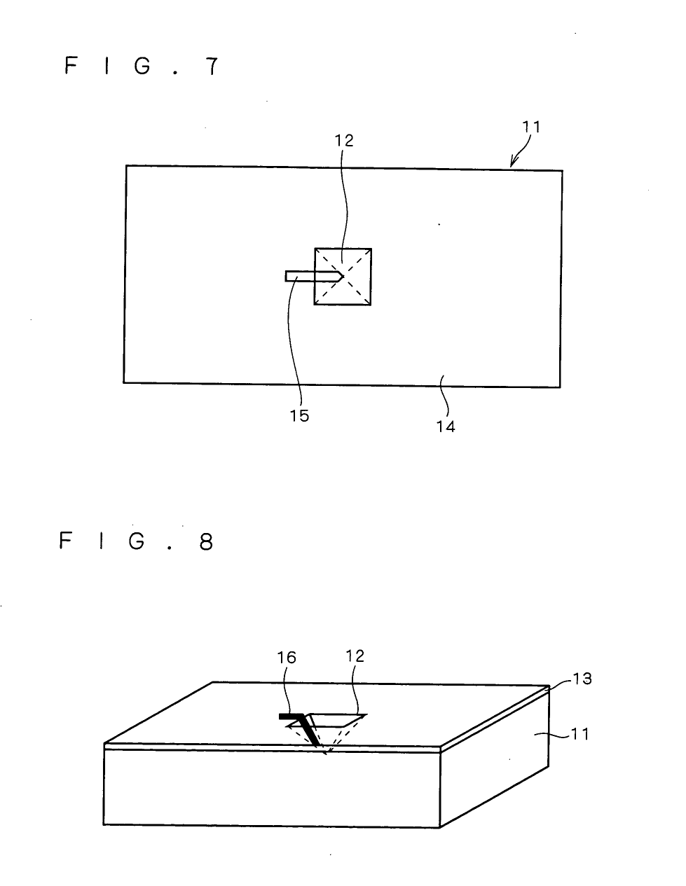

Next, a photoresist 15 is applied on the tungsten film 14, and the photoresist 15 is patterned to be a determined shape by a lithography process. An appearance of this patterned photoresist 15 is illustrated in FIG. 6. Moreover, a plane view of it is illustrated in FIG. 7.

Next, by performing an anisotropy dry etching with using the photoresist 15 patterned to be the determined shape as the mask, a tungsten wiring 16 is placed as shown in FIG. 8. That tungsten wiring 16 is placed so that one edge reaches a peak of the hole having the square pyramidal shape in one surface of the hole 12 having the square pyramidal shape and an opposite edge part is salient from that hole 12 having the square pyramidal shape from that peak through a center part of the one surface.

By that placement, a length of the tungsten wiring 16 becomes the shortest. Here, a width of a line of the tungsten wiring 16 is approximately 10 nm. Besides, a condition that the photoresist 15 is removed is illustrated in FIG. 8.

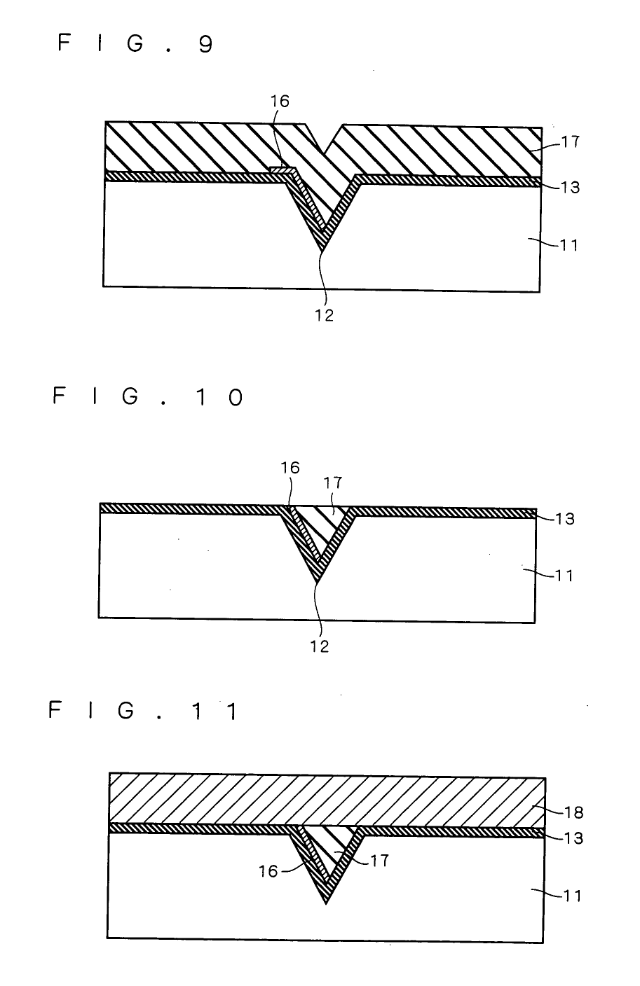

Next, in the meantime, by employing the CVD method, a silicon nitride film 17 is formed in a thickness of approximately 20 μm to cover the silicon oxide film 13 and the tungsten wiring 16 as shown in FIG. 9.

Here, the silicon nitride film 17 is applied by reason that it has a selective etching rate to the silicon oxide film 13. Accordingly, the other material can also be selected except for the silicon oxide film 13 and the silicon nitride film 17, when the selective etching rate is included between them. Besides, the higher that selective etching rate, the more a damage to the cantilever to be completed by that etching can be controlled.

Next, by employing a CMP (Chemical and Mechanical Polishing), part of the silicon nitride film 17 and the tungsten wiring 16 are polished until the silicon oxide film 13 is exposed as shown in FIG. 10.

According to this, the silicon nitride film 17 and the tungsten wiring 16 remain only in the hole 12 having the square pyramidal shape where the sacrifice film 13 is formed.

Next, by a vacuum deposition, a platinum film 18 is formed in a thickness of approximately 5 μm to cover the silicon oxide film 13, the silicon nitride film 17 and the tungsten wiring 16 as shown in FIG. 11. Here, the other material which has a conductivity is also applicable except for the platinum film 18.

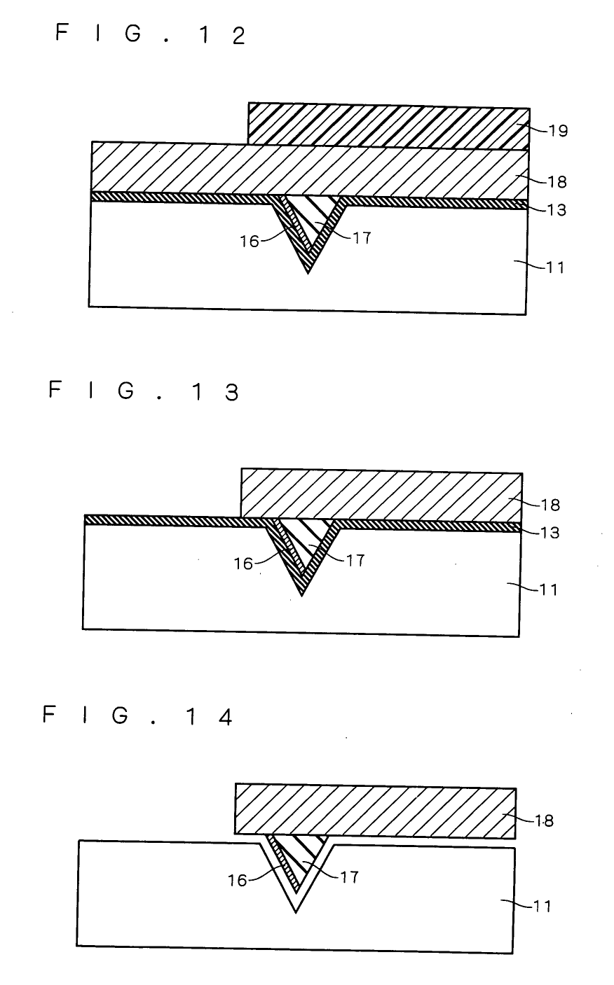

Next, a photoresist 19 is applied on the platinum film 18, and the photoresist 19 is patterned to be a determined shape by a lithography process. An appearance of this patterned photoresist 19 is illustrated in FIG. 12.

Next, by performing an anisotropy dry etching with using the photoresist 19 patterned to be the determined shape as a mask, as shown in FIG. 13, the platinum film 18 is patterned to be a shape as the electrode part 2 of the cantilever shown in FIG. 1. Besides, a condition that the photoresist 19 is removed is illustrated in FIG. 13.

Finally, by immersing the single crystal silicon substrate 11 on the way of manufacturing that each material is formed as shown in FIG. 13 in a hydrofluoric acid solution and performing an etching treatment, the silicon oxide film 13 which is a sacrifice film is removed, and by that removal, the materials formed upward (the tungsten wiring 16, the silicon nitride film 17 and the platinum film 18) are separated (lifted-off) from the single crystal silicon substrate 11 as shown in FIG. 14.

According to the steps described above, the cantilever according to FIGS. 1 and 2 can be formed.

The probe part 1 of the cantilever according to the present invention includes the insulator 1a having the square pyramidal shape and the conductive wiring 1b having a linear shape which is placed only on one surface of that insulator 1a having the square pyramidal shape, thus by applying that cantilever to the SCM, the surface resolution capability of the SCM can be made to improve furthermore as compared with a case of applying the cantilever that the entire surface of the insulator having the square pyramidal shape is coated with the conductor.

That is to say, an electrostatic capacity is a long-distance force, thus with regard to a measurement of the electrostatic capacity by the SCM, it is also under the influence of the conductor of a part which does not relate to the measurement directly (a part except for the extreme edge part of the probe part 1). Moreover, the electrostatic capacity between the conductor part of the probe part 1 and the sample changes in proportion to an area which they face with each other.

Accordingly, by reducing the facing area of the conductor except for the extreme edge part of the probe part relating to the direct measurement with the sample, the change of the electrostatic capacity described above can be controlled (that is to say, the influence of the conductor of the part which does not relate to the measurement directly can be controlled), and thus the surface resolution capability of the SCM can also be made to improve corresponding to that control.

When applying a contrivance described above to a case of placing the conductor 1b which becomes a measurement part on one surface of the insulator 1a having the square pyramidal shape, the facing area of the conductor part which does not relate to the measurement directly with the sample can be reduced more in the case of placing the conductive wiring 1b having the linear shape on one surface such as the present invention than the case that the entire surface of one surface of that insulator 1a is coated with the conductor, and by just that much, the electrostatic capacity between the conductor part which does not relate to the measurement directly and the sample can be made to reduce. Accordingly, corresponding to this, the surface resolution capability of the SCM can also be made to improve.

Moreover, when the one edge of the conductive wiring 1b reaches the peak of the insulator 1a having the square pyramidal shape and the opposite edge reaches the electrode part 2, the conductive wiring 1b can be placed with any shape, however, as described above, the length of the conductive wiring 1b can be the shortest by placing it to go through the center part of the one surface of the insulator 1a having the square pyramidal shape, and the surface resolution capability can be made to improve furthermore.

Moreover, by reason that the conductive wiring 1b has a linear shape, a mechanical strength becomes weak, however, the conductive wiring 1b is supposed to be placed closely on the surface of the insulator 1a having the square pyramidal shape, therefore, it is also possible to control the mechanical strength of that conductive wiring 1b becoming weak.

Moreover, the manufacturing method that the single crystal silicon substrate 11 where the hole 12 having the square pyramidal shape is formed is prepared, the sacrifice film is formed on that single crystal silicon substrate 11 and the materials to be the cantilever are formed on that sacrifice film (the insulator 1a of the probe part 1 of the cantilever has a large selective etching rate to the sacrifice film) is applied, thus by removing the sacrifice film by the etching treatment, the cantilever according to the present invention can be formed easily by the lift-off, and moreover, controlling the damage to the cantilever.

In the present invention, the specification are proceeded in a limitation of the square pyramidal shape as the probe, however, it is not limited to this, but probes having arbitrary pyramidal shapes (including conical shape) are also applicable. In this case, the wiring such as tungsten and so on is supposed to be formed on an arbitrary part of a surface of the probe having the pyramidal shape.

While the invention has been shown and described in detail, the foregoing description is in all aspects illustrative and not restrictive. It is therefore understood that numerous modifications and variations can be devised without departing from the scope of the invention.

What is claimed is:

1. A cantilever, comprising:
a probe part scanning an observed sample and an electrode part supporting said probe part, wherein
said probe part includes:
an insulator having a sharp-pointed solid shape and
a conductive wiring which is placed on a part of a side surface of said insulator, having one end reaching a peak of said solid shape and an opposite end reaching said electrode part.

2. The cantilever according to claim 1, wherein
said conductive wiring is placed so as to be shortest in length.

3. A manufacturing method of a cantilever, comprising the steps of:
(a) forming a hole having a sharp-pointed solid shape in a surface of a substrate so that a peak is formed inside of said substrate;
(b) forming a sacrifice film to cover said surface of said substrate and a side surface of said hole having said solid shape;
(c) forming a conductive wiring in a side surface part of said hole having said solid shape on said sacrifice film so that one end reaches a peak of said hole having said solid shape;
(d) forming an insulator having a selective etching rate to said sacrifice film to fill up said hole having said solid shape after said step (c);
(e) forming an electrode part to cover an upper surface of said insulator, an opposite end of said conductive wiring and said sacrifice film; and
(f) separating said insulator, said conductive wiring and said electrode part from said substrate by etching said sacrifice film after said step (e).

4. The manufacturing method of the cantilever according to claim 3, wherein
said step (c) includes the step of:
forming said conductive wiring so that the length from said sharp point of said hole having said solid shape to said surface of said substrate becomes shortest.
